(19) United States
(12) Patent Application Publication
(10) Pub. No.: US 2025/0038034 A1
(43) Pub. Date: Jan. 30, 2025

(54) METHOD AND APPARATUS FOR RADIO FREQUENCY GRID DESIGN IN AN ESC TO REDUCE FILM ASYMMETRY

(71) Applicant: Lam Research Corporation, Fremont, CA (US)

(72) Inventors: Stephen Topping, Portland, OR (US); Patrick G. Breiling, Tigard, OR (US); Sergey Georgiyevich Belostotskiy, Sherwood, OR (US); Ramesh Chandrasekharan, Lake Oswego, OR (US); Timothy Scott Thomas, Wilsonville, OR (US); Mahmoud Vahidi, Lake Oswego, OR (US); Yukinori Sakiyama, West Linn, OR (US); David French, Fort Myers, FL (US); Meenakshi Mamunuru, Freemont, CA (US); Ashish Saurabh, Portland, OR (US); Pramod Subramonium, Portland, OR (US); Noah Elliot Baker, West Linn, OR (US)

(21) Appl. No.: 18/834,982

(22) PCT Filed: Jan. 24, 2023
(86) PCT No.: PCT/US2023/011463

§ 371 Date: Jul. 31, 2024

Related U.S. Application Data
(60) Provisional application No. 63/267,378, filed on Jan. 31, 2022.

(51) Int. Cl. H01L 21/683; H01J 37/32

(52) U.S. Cl. CPC H01L 21/6833; H01J 37/32715; H01J 2237/2007

(57) ABSTRACT

Electrostatic chuck (ESC) apparatuses and systems are provided. An ESC may have one or more chucking electrodes and a blocking electrode that surrounds the chucking electrodes. The blocking electrode may reduce non-uniformities in semiconductor processing operations performed with the ESC. In some implementations, the blocking electrode is positioned beneath the chucking electrodes.

### INCORPORATED BY REFERENCE

A PCT Request Form is filed concurrently with this specification as part of the present application. Each application that the present application claims benefit of or priority to as identified in the concurrently filed PCT Request Form is incorporated by reference herein in its entirety and for all purposes.

### BACKGROUND

Semiconductor processing tools commonly include one or more semiconductor processing chambers that provide an isolated environment within which to process semiconductor wafers. In some semiconductor processing tools, multiple semiconductor wafers may be processed within a single chamber. In such semiconductor processing tools, such a chamber may include a plurality of wafer processing stations, each having its own wafer support or pedestal. In some embodiments, the pedestal may be an electrostatic chuck (ESC) that may be used to generate an electromagnetic field that clamps the substrate to the ESC and/or bias towards the ESC.

Semiconductor processing tools may be used to perform plasma-based processing operations on semiconductor wafers. Plasma sources are used to create a plasma that, when a process gas is flowed into them, creates neutral particles, ions, and/or radicals of the process gas. These particles may then be flowed to react physically and/or chemically with a substrate of interest. Electrodes in an electrostatic chuck (ESC) or pedestal on which the substrate rests may be used to generate an electric field that may clamp the substrate to the pedestal and/or bias particles to the pedestal.

Background and contextual descriptions contained herein are provided solely for the purpose of generally presenting the context of the disclosure. Much of this disclosure presents work of the inventors, and simply because such work is described in the background section or presented as context elsewhere herein does not mean that it is admitted to be prior art.

### SUMMARY

Disclosed herein are methods and systems of operating a process chamber having an electrostatic chuck. In one aspect of the embodiments herein, an apparatus including an electrostatic chuck (ESC) for supporting a semiconductor substrate is disclosed, the ESC including: an upper surface for supporting a wafer; one or more clamping electrodes beneath the upper surface, wherein the one or more clamping electrodes are configured to, when powered, electrostatically clamp the wafer to the upper surface; a blocking electrode, wherein the blocking electrode includes: an annular portion, a center portion, and three or more spokes, wherein each spoke has a distal end coupled to the annular section and a proximal end coupled to center portion, wherein the annular section surrounds the one or more clamping electrodes when viewed along an axis perpendicular to the upper surface.

In some embodiments, the one or more clamping electrodes are configured to be powered by an RF source. In some embodiments, a distance between a top surface of the blocking electrode and a bottom surface of the one or more clamping electrodes is between about 0.05 and about 0.2 inches. In some embodiments, interior corners formed where each of the three or more spokes is coupled to the annular portion are rounded. In some embodiments, the three or more spokes are arranged in a radially symmetric pattern. In some embodiments, there are 2·n spokes, where n is an integer greater than one. In some embodiments, the three or more spokes are 10 spokes. In some embodiments, the one or more clamping electrodes are two clamping electrodes. In some embodiments, the two clamping electrodes are configured to, when powered by a radio frequency (RF) source, operate at a positive and negative polarity, respectively. In some embodiments, the two clamping electrodes are nominally semicircular electrodes. In some embodiments, the one or more clamping electrodes are planar. In some embodiments, the blocking electrode is planar.

In some embodiments, the blocking electrode includes a metal mesh. In some embodiments, the blocking electrode includes a single piece of metal. In some embodiments, the apparatus further includes an RF power source, and wherein the number of spokes of the blocking electrode is based on a frequency of the RF power source. In some embodiments, the one or more clamping electrodes are parallel to the blocking electrode and between the blocking electrode and the upper surface. In some embodiments, one or more clamping electrodes are at least two clamping electrodes, and wherein at least one spoke of the three or more spokes are aligned with a gap between the one or more clamping electrodes when viewed along the first axis. In some embodiments, each spoke has a width measured in a direction perpendicular to the first axis and the proximal and distal ends of each spoke, and wherein a ratio between the total width of all spokes and the inner circumference of the annular section is greater than about 1:10. In some embodiments, the apparatus further includes lift pins that do not intersect the three or more spokes.

In some embodiments, the apparatus further includes a process chamber that contains the ESC. In some embodiments, the apparatus further includes a rotational indexer. In some embodiments, the rotational indexer includes a central hub and an indexer arm, the central hub rotatable relative to the chamber about a first axis nominally located at the center of the circular pattern, each indexer arm having a proximal end fixedly mounted to the central hub and a distal end that supports a rotatable wafer support that is configured to rotate about a corresponding second axis relative to the indexer arms, and wherein the apparatus further includes a controller that includes one or more processors and one or more memories, wherein the one or more processors, the one or more memories, the ESC, the indexer, and the process chamber are operably connected with each other, and the one or more memory devices store computer-executable instructions for controlling the one or more processors to: cause a wafer located on the ESC to be placed on the rotatable wafer support; cause the rotatable wafer support and the wafer supported thereby to rotate about the corresponding second axis by an amount based at least in part on an angle between two adjacent spokes of the three or more spokes of the blocking electrode; and cause the wafer to be placed back onto the ESC.

These and other features of the disclosed embodiments will be described in detail below with reference to the associated drawings.

### BRIEF DESCRIPTION OF DRAWINGS

FIG. 1 presents a perspective view of a blocking electrode that is coplanar with two chucking electrodes.

FIG. 2 presents a chart of thickness as a function of theta for semiconductor wafers processed using various blocking grid designs.

FIG. 3 presents a side view of a process chamber having an electrostatic chuck according to various embodiments disclosed herein.

FIGS. 4a and 4b present perspective and top views of chucking and blocking electrodes according to various embodiments disclosed herein.

FIG. 5 presents a chart of non-uniformity as a function of theta for semiconductor wafers processed using blocking grids having two, four, or ten spokes.

FIGS. 6a and 6b present alternative blocking electrode designs having 8 and 10 spokes, respectively.

FIG. 6c presents an alternative clamping electrode design having interdigitated electrodes.

FIG. 7 presents a cut-out view of a blocking electrode having a fillet between the spoke and the outer ring.

FIG. 8 presents a schematic view of a blocking electrode indicating spoke widths and arc lengths.

FIG. 9 presents a schematic view of a rotational indexer.

FIG. 10 presents a side-view of a rotational indexer.

### DETAILED DESCRIPTION

This disclosure relates to electrostatic chucks (ESC) used in semiconductor processing. In semiconductor processing equipment, an electrostatic chuck is commonly used for clamping a substrate to a pedestal during a plasma process. The electrostatic chuck clamps the substrate by creating an attractive force between the substrate and the chuck. A chucking voltage is applied to one or more electrodes in the ESC to induce oppositely polarized charges in the substrate and the electrodes, respectively. In some embodiments, the electrodes may also be referred to as “grids.” Various designs may be used to accomplish clamping. In a monopolar ESC having one electrode, the one electrode may have a voltage applied, and an opposite charge may be induced in the substrate using, e.g., a plasma generated above the substrate.

In a bipolar electrostatic chuck, the electrostatic chuck has a pair of coplanar chucking (or clamping) electrodes embedded within a pedestal structure and each electrode is respectively connected to a terminal of a power supply or other system configured to apply an electrical potential to the electrodes. The opposite charges interact with the substrate, in particular a bottom surface of the substrate, to pull the substrate against the electrostatic chuck, thus clamping the substrate to the chuck. In some embodiments the clamping electrodes are each “D-shaped,” but other shapes may be used, including interdigitated clamping electrodes or concentric clamping electrodes. The electrodes may be positioned such that they are underneath a wafer placed upon the substrate.

A blocking electrode (also known as an “outer electrode,” “edge electrode,” or “averaging electrode”) may also extend around the chucking electrodes. The blocking electrode may have an annular portion 122 that, when viewed from above, encircles the chucking electrodes. The blocking electrode may average anomalies associated with the positive and negative polarities of the chucking electrodes, smoothing the interaction of the chucking electrodes with the wafer. The blocking electrode may also interact with a plasma above the wafer during wafer processing operations to improve processing uniformity.

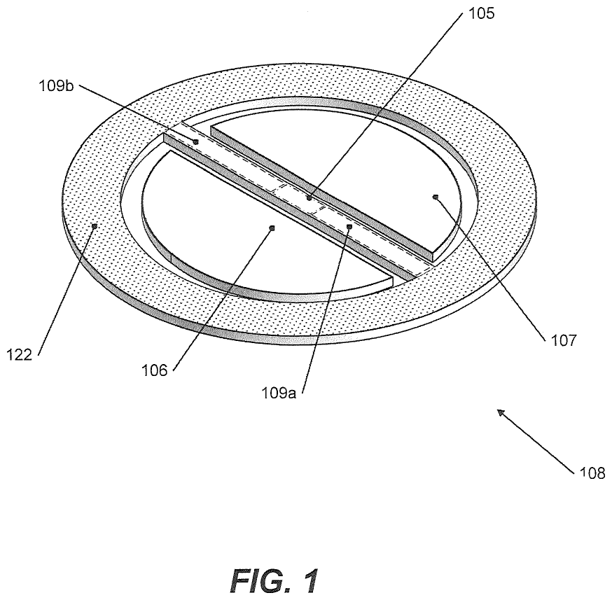

FIG. 1 presents a perspective view of an example of a bipolar electrostatic chuck having two clamping electrodes 106 and 107, encircled by a blocking electrode 108. Blocking electrode 108 has an annular portion 122 (shaded), along with two spokes 109a and 109b (it should be understood that spokes generally span from a center region 105 to the annular portion, such that a strip spanning the diameter, as shown in FIG. 1, would be two spokes). The spokes may connect to a center region 105, which may be electrically coupled to a power source, e.g., by leads that pass through a pedestal that supports the electrostatic chuck in which the electrodes are located.

ESCs may be manufactured using a sintering process. The electrodes, as well as other elements in the pedestal/ESC and electrical connectors, e.g., metal wires, may be positioned in a powder that may be heated and/or compressed to sinter the powders together, forming a pedestal having each of the components noted above embedded within. The powder may be a ceramic, e.g., alumina or alumina nitride, that forms a single piece during sintering. In some embodiments, the powder may be in an “unfired” state that may be easily machinable. An ESC may be built by layering components/powder together and then firing the entire ESC to sinter the ceramic powder. As the sintering process results in expansion/contraction of various elements in the pedestal and thus movement of those elements (and potential defects due to such movement), manufacturing may be simplified by aligning components in fewer planes. Thus, the clamping electrodes and blocking electrodes are typically co-planar to reduce manufacturing costs. Furthermore, connections to each of the components, e.g., electrical connections to the electrodes, may be positioned along a vertical central axis to reduce manufacturing complexity.

In some implementations, the blocking electrodes and/or the clamping electrodes may be a thin sheet of electrically conductive material, e.g., metal, machined to have shapes as described herein. In some implementations, the electrodes may have multiple components. In some implementations, the electrodes may have slots or holes or be made of a mesh that allow the movement of particles therethrough; this may reduce the risk of delamination after sintering, as the ceramic particles may sinter through the electrodes rather than merely around them. In some implementations, the electrodes may be a metallic mesh, e.g., a woven mesh having multiple metal strands that overlap and are electrically connected. Regardless of the particular details of the electrode material, the electrodes may be machined into shapes such as are discussed herein.

Generally, the blocking electrode may improve the uniformity of processing operations performed on the substrate. RF power provided to the blocking electrode may control the area where a plasma forms, particularly the radius of the plasma. As plasma processes may have non-uniformities from center-to-edge resulting from the plasma, the RF power delivered to the blocking electrode and the clamping electrodes may be tuned to control the plasma and improve uniformity. However, the blocking electrode may also cause some non-uniformities, e.g., non-uniformities corresponding to the spokes 109a-b, particularly near the radial edge of the substrate. Without being bound by theory, coupling between the blocking electrode and the wafer, along with variations in RF density between the spokes and the annular portion of the blocking electrode is thought to affect processing operations by increasing non-uniformity corresponding with the location of the center strip.

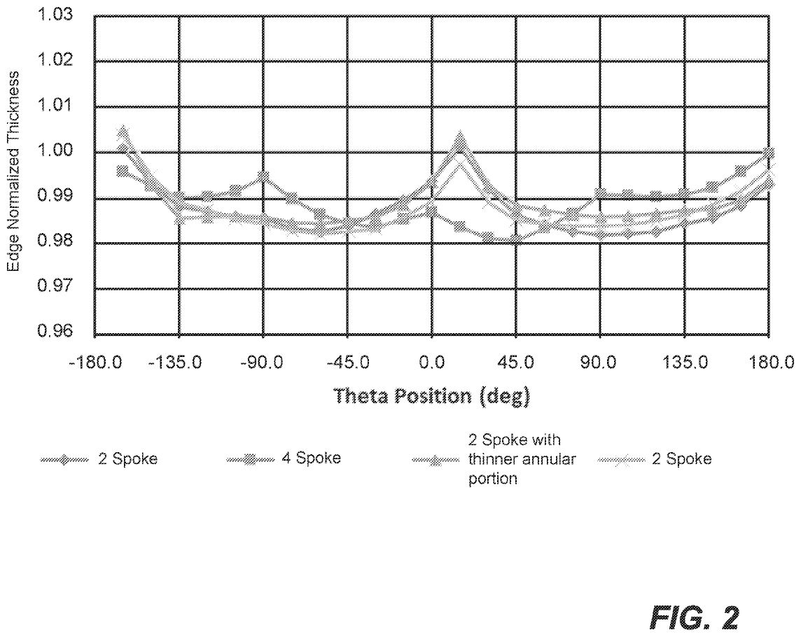

FIG. 2 presents a chart of uniformity as a function of azimuthal position for measurements taken near the outer edge of wafers. There are two data sets for a two-spoke model, a data set for 4-spoke model, and a data set for a 2-spoke model where the inner diameter of the annular portion of the blocking electrode is larger (resulting in a radially thinner annular portion). The two-spoke model lines correspond with a blocking electrode and clamping electrodes design shown in FIG. 1. As may be seen, there is a large peak at 0 and 180 degrees, which, for this data, corresponds with where the spokes 109a-b couple to the annular portion of the blocking electrode. This non-uniformity in thickness is undesirable. In some embodiments, such non-uniformity may be reduced by rotating the wafer between processing operations. For example, by rotating the wafer 90 degrees halfway through a processing operation, the non-uniformity may be reduced at 0 and 180 degrees and increased at 90 and 270 degrees, reducing the magnitude of peaks in non-uniformity at any given radial location. While reducing peak non-uniformity may be desirable, it is also generally desirable to reduce average non-uniformity.

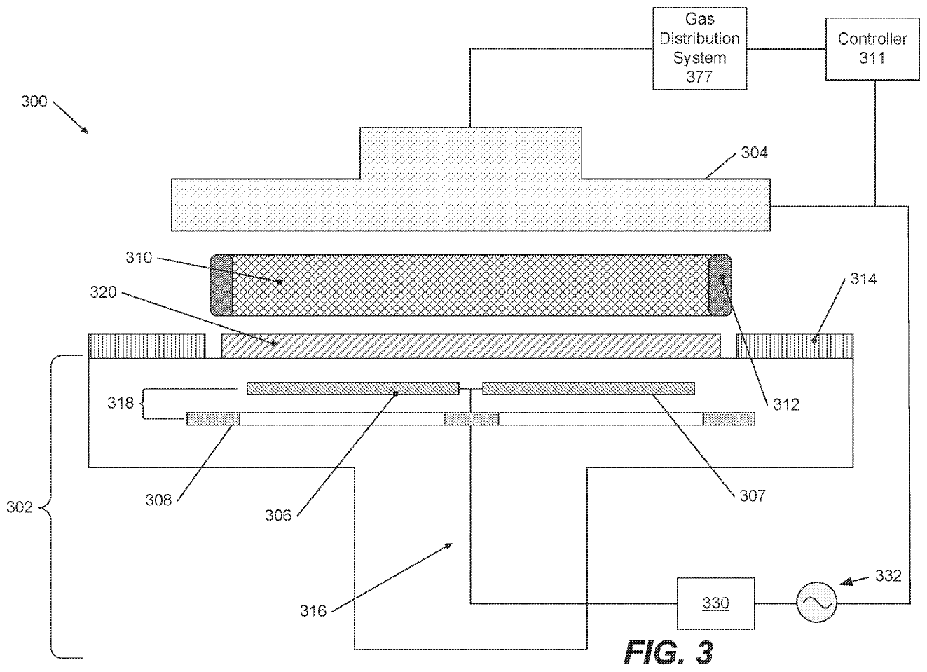

This disclosure describes various features that may be employed in ESC designs, either in combination or individually, to reduce non-uniformities in processing operations. In one embodiment, FIG. 3 presents a side view of a process chamber 300. The process chamber may be used in conjunction with systems or components used for various plasma processing techniques, such as plasma-enhanced chemical vapor deposition, plasma etching, plasma stripping or ashing, sputtering, plasma spraying, and the like. The process chamber may include an electrostatic chuck (ESC) 302 that supports a substrate 320 (an ESC may also be referred to as a pedestal herein). ESC 302 comprises a blocking electrode 308 and chucking electrodes 306 and 307. The blocking electrode and chucking electrodes may have one or more electrical leads 316 that electrically connect, either directly or indirectly, the electrodes to one or more power supplies 332, which may provide DC and/or RF power to each of the electrodes.

ESC 302 may be configured to support a wafer 320 that may be provided to process chamber 300. The wafer, which may also be referred to as a substrate or semiconductor substrate, may be a silicon or other semiconductor wafer, e.g., a 200-mm wafer, a 300-mm wafer, or a 450-mm wafer, including wafers having one or more layers of material, such as dielectric, conducting, or semi-conducting material, deposited thereon. It should be understood that the process chamber and ESC described herein are designed for a 300 mm wafer. Suitable modifications may be made to scale various elements for larger or smaller wafers (e.g., the electrodes may be scaled to correspond with the wafer diameter to be processed).

A ring 314, e.g., an edge ring or exclusion ring, may also be positioned on the ESC 302. Ring 314 may be a ceramic ring that protects, e.g., the pedestal/ESC in the process chamber from damage from the plasma and/or may assist in controlling the plasma. In some embodiments ring 314 may be a replaceable component.

A showerhead 304 may be positioned above the ESC. During processing operations, process gases may be flowed through the showerhead toward the wafer. During operation a plasma 310 is formed above the wafer 320. In some embodiments, the showerhead includes or is otherwise coupled to a plasma generation system (not shown) that may be used to generate a plasma. Showerhead 304 (or a plasma generator system) and ESC 302 (including the clamping electrodes and blocking electrode) may be electrically coupled to an RF power supply 332 and matching network 330 for powering a plasma. During operation, RF power supply 332 and matching network 330 may be operated at any suitable power to form a plasma having a desired composition of species. Plasma 310 has a plasma edge region 312 that is near the outer edge of the wafer 320.

To control a manner in which the RF power supply 332 operates, the controller 311 is operatively coupled therewith. The controller 311 may be an analog controller, a discrete logic controller, a programmable array controller (PAL), a programmable logic controller (PLC), a microprocessor, a computer or any other device capable of carrying out operations for effecting processing operations. In one exemplary embodiment, the controller determines a magnitude of power to be supplied to each of the showerhead, clamping electrodes, and blocking electrodes, and provides commands to the RF power supply 332. In addition to controlling the RF power supply 332, the controller 311 may also be operatively coupled to a gas distribution system 377 and may provide commands thereto to supply an amount of processing gas towards the wafer.

Gas distribution system 377 may be coupled to one or more gas sources and include one or more corresponding valves or other flow control components (e.g., mass flow controllers and/or liquid flow controllers). Controller 311 may be connected to the one or more valves or other flow control components to cause them to switch states and thereby allow different gases or combinations of gases to be flowed at different times and/or flow rates. In some embodiments the one or more gas sources may be fluidically connected to a mixing vessel to allow for blending and/or conditioning of process gases prior to flow over the wafer.

The RF power supply 332 may be a radio frequency (RF) energy source or other source of energy capable of supplying power to and energizing electrodes to form an electric field. In an exemplary embodiment, the RF power supply 332 includes an RF generator that is configured to operate at a desired frequency. For example, the RF generator may be configured to operate within a frequency range of 0.2 MHz to 20.0 MHz. In one exemplary embodiment, the RF generator may operate at 13.56 MHz. In an exemplary embodiment, the RF power supply 332 may include matching network 330 disposed between the RF generator and one or more elements described herein, e.g., the plasma generator system or ESC. The matching network may be an impedance matching network that is configured to match an impedance of the RF generator to an impedance of electrodes connected to the RF generator. In this regard, the matching network may be made up of a combination of components, such as a phase angle detector and a control motor; however, in other embodiments, it will be appreciated that the matching network may include other or additional components as well.

As noted above, a wafer may have non-uniformities from processing operations. Various designs of the ESC, and in particular various designs of the clamping electrodes and blocking electrodes, may reduce such non-uniformities, and in particular non-uniformities that correspond to the clamping and/or blocking electrodes.

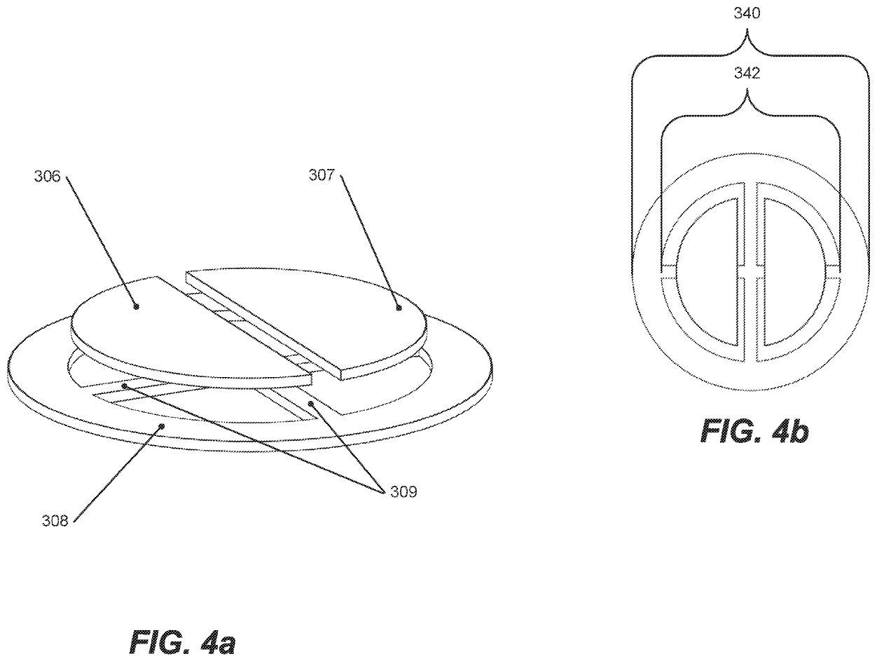

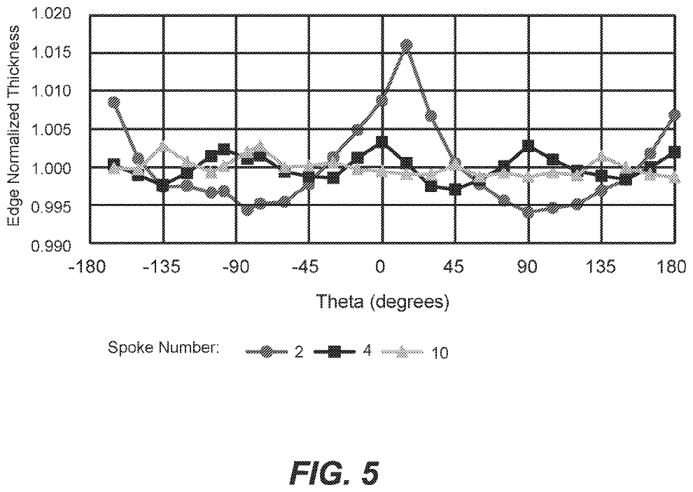

FIGS. 4a and 4b present a perspective and top-down view, respectively, of one embodiment of clamping electrodes 306 and 307 and blocking electrode 308. As may be seen, blocking electrode 308 has four spokes 309. FIG. 4b shows a top down view, illustrating an overlap between the clamping electrodes and the spokes of the blocking electrode. In some embodiments, increasing the number of spokes decreases the peak non-uniformity at the wafer edge associated with the spokes. FIG. 5 presents a chart of uniformity as a function of azimuthal position along a wafer edge for two-, four-, and ten-spoke blocking electrodes. A two-spoke blocking electrode has a peak at 0 and 180 degrees, similar to the peak seen in FIG. 2. The four-spoke blocking electrode shows peaks of non-uniformity at 90-degree increments, while the ten-spoke blocking electrode shows some peaks of non-uniformity at some multiples of ˜36 degrees. Importantly, the reduction in non-uniformity from additional spokes is greater than simply averaging out the two-peak non-uniformity of the two-spoke blocking electrode to four-peaks. Rather, the use of additional spokes decreases the average non-uniformity as well as localized peak non-uniformity. Thus, increasing the number of spokes for the blocking electrode may provide a significant improvement in uniformity for processing operations. In some embodiments, a blocking electrode may have at least three spokes, at least four spokes, at least six spokes, at least ten spokes, at least twelve spokes, or about sixteen spokes. In some embodiment, the number of spokes may be an even integer. Even integer numbers of spokes may be preferable to maintain symmetry across the wafer. However, in some embodiments, the number of spokes may alternatively be an odd integer.

In some embodiments, the clamping electrodes may be semicircular, such as shown in FIGS. 4a and 4b. In embodiments using a two-spoke blocking electrode, the two clamping electrodes and the blocking electrode may be coplanar, as the two spokes of the blocking electrode may pass through a gap between the clamping electrodes. However, in embodiments using two clamping electrodes and more than two spokes in the blocking electrode, there is insufficient space for the blocking electrode and the clamping electrodes to be coplanar without reducing the size of the clamping electrodes so that they fit in the spaces in between the spokes. Thus, in some embodiments the blocking electrode may be positioned beneath the clamping electrodes such that the clamping electrodes are between the blocking electrode and the wafer. FIGS. 3 and 4a illustrate such a relative position between the blocking electrode and the clamping electrodes.

In some embodiments, as the blocking electrode may be placed underneath the clamping electrodes, the blocking electrode may interact with other components of the ESC. For example, the blocking electrode may also capacitively couple with heating elements within the ESC. Typically, the heating elements are positioned away from the clamping electrodes to reduce any coupling effects, however the lower placement of the blocking electrode may cause the blocking electrode to electrically interact with the heating elements, which can reduce the efficiency of the blocking electrode and cause non-uniformities in the processing operation. Thus, it is desirable to have the blocking electrode away from the heating elements, and thus closer to the clamping electrodes, to minimize any capacitive coupling with the heating elements.

However, in some cases, positioning the blocking electrode below the clamping electrodes may improve the ability of the blocking electrode to influence the plasma above the wafer. As wafer edge defects are a significant source of defects, the plasma edge region 312 may be tuned during or between processing operations to reduce potential defects and/or non-uniformities by, e.g., changing the power provided to the blocking electrode. When the blocking electrode is positioned vertically closer to the top of the ESC relative to the clamping electrodes, a stable process window for powering the blocking electrode and clamping electrodes may be centered at edge-focused processing values, such that there is a higher plasma density near the wafer edge. In some embodiments this may be undesirable as limiting the tuneability of the RF power to influence plasma properties. Thus, in some embodiments, the lower positioned blocking electrode may shift the stable process window such that the center of the stable process window results in a more uniform edge-to-center plasma density, allowing more control of the plasma properties using RF power to the blocking and clamping electrodes.

Thus, in some embodiments the blocking electrode may be a distance 318 below the clamping electrodes (where the blocking electrode and clamping electrodes are substantially parallel to each other and the wafer). In some embodiments, distance 318 is about 0.1 inches, or between about 0.05 inches and about 0.2 inches. These distances may balance the concern in reducing capacitive coupling with other components in the ESC with the benefit of better control of the plasma via the blocking electrode. Distance 318 may also affect how the blocking electrode interacts with other components in the ESC. In addition to the above, a larger distance 318 may allow the blocking electrode to have more process space control over the plasma.

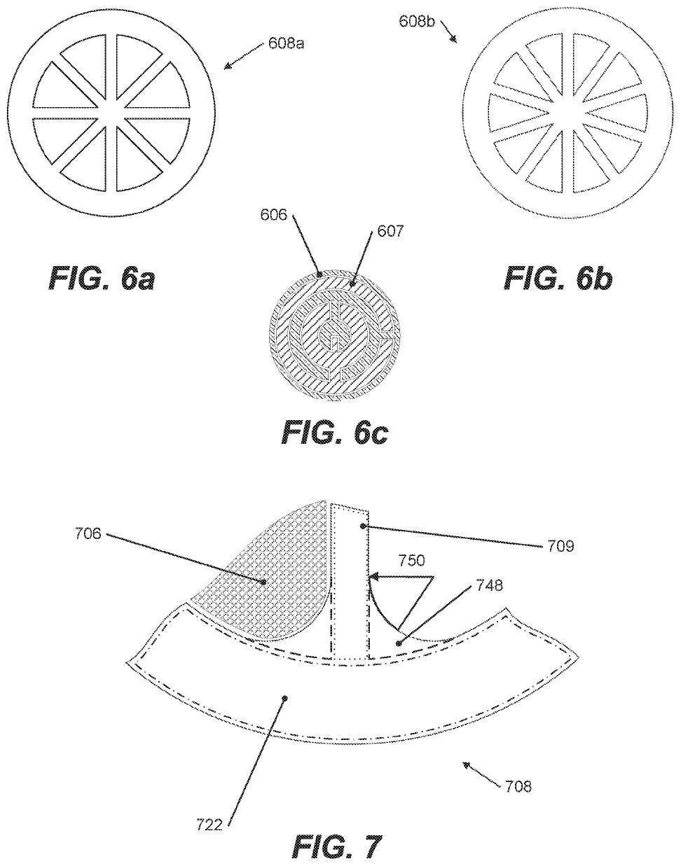

In some embodiments, the number of clamping electrodes may be based on the number of spokes. For example, if there are four spokes, there may be four clamping electrodes, each having a 90 degree are shape to fit within the space between the spokes and annular portion of the blocking electrode. In such embodiments, the clamping electrodes and the blocking electrode may be co-planar or the blocking electrode may be below the clamping electrodes. Furthermore, while two clamping electrodes are shown in the drawings, it should be understood that there may only be one clamping electrode (e.g., with the blocking electrode positioned at a lower elevation than the clamping electrode) or multiple, e.g., two or more than two, clamping electrodes. In some embodiments the clamping electrodes may be interdigitated (an example of an interdigitated electrode is shown in FIG. 6c, having two interdigitated electrodes 606 and 607). In some embodiments the clamping electrodes may have various configurations, e.g., a single clamping electrode, interdigitated electrodes, etc.

In some embodiments, the clamping electrodes and the blocking electrode may be configured to reduce or minimize overlap between the blocking electrode and the clamping electrodes. Overlap is generally undesirable as the clamping electrode and the blocking electrode may electrically couple, reducing the polarization between the wafer and the clamping electrodes and affecting processing operations. Thus, in some embodiments, any gaps between the clamping electrodes may be horizontally aligned with one or more spokes of the blocking electrode to reduce overlap, as shown in, e.g., FIG. 1. In other embodiments, it may be desirable to misalign the spokes and any gaps between the clamping electrodes. For example, misaligning the spokes and any gaps may improve symmetry of the coupling between the blocking electrode and the clamping electrodes. As will be discussed further herein, a wafer processed on an ESC as described herein may be rotated to minimize any non-uniformities resulting from coupling between the blocking and clamping electrode. Misaligning the spokes and any gaps between the clamping electrodes may facilitate each of the spokes causing similar non-uniformities. Thus, when a wafer is rotated on the ESC, the non-uniformity resulting from each spoke may be similarly, azimuthally distributed across the substrate.

The blocking electrode has an outer diameter 340 and an inner diameter 342. The inner diameter refers to an inner diameter of the annular portion of the blocking electrode (e.g., excluding the spokes). In some embodiments, the inner diameter is at most about the diameter of a wafer to be processed using the blocking electrode (e.g., about 300 mm or less or about 11.8 inches or less). In some embodiments, the inner diameter is less than about 300 mm. In some embodiments, the outer diameter is at least the diameter of the wafer. In some embodiments, the outer diameter is about 13.3 inches±0.1 inches. In some embodiments, the inner diameter is about 11.3 inches±0.1 inches. In some embodiments, the inner diameter is about 11.8 inches±0.1 inches. In some embodiments, increasing the inner diameter of the annular portion may reduce coupling of the blocking electrode with the wafer, reducing non-uniformities at the wafer edge

FIGS. 6a and 6b present views of blocking electrodes 608a and 608b having eight and ten spokes, respectively. Generally, additional spokes reduce non-uniformities. However, in some embodiments the number of spokes may be limited by other elements in the ESC. For example, pedestals may include lift pins that support the wafer for a wafer handling robot to place upon or remove therefrom. The lift pins or associated components may need to pass through the plane of the blocking electrode, such that additional spokes may significantly impact the clearance for the pins (or requiring that the larger number of spokes be arranged asymmetrically in order to clear such features, which may act to increase wafer non-uniformities). Thus, in some embodiments the number of spokes may be limited based on the position of the lift pins so that the lift pins do not intersect with the spokes of the blocking electrode and the spokes can still be arranged in a generally radially symmetric manner. In some embodiments, there are twelve or fewer spokes, ten or fewer spokes, or eight or fewer spokes. In some embodiments, the spokes are evenly azimuthally spaced.

In some embodiments, the number of spokes may be determined based on frequencies of RF power used with the electrodes. For example, the electrode design may lead to an interaction with the harmonics of the RF power, which may affect processing operations and are generally undesirable. Thus, in some implementations, for grids designed to be used at RF frequencies, the arc length of the annular portion between spokes may be less than about ¼ of the guided wavelength of the highest harmonic of the RF drive frequency to reduce the emission of harmonic frequencies. For example, for grids used in systems using an RF power at 13.56 MHz, the arc length may be less than about 18 cm.

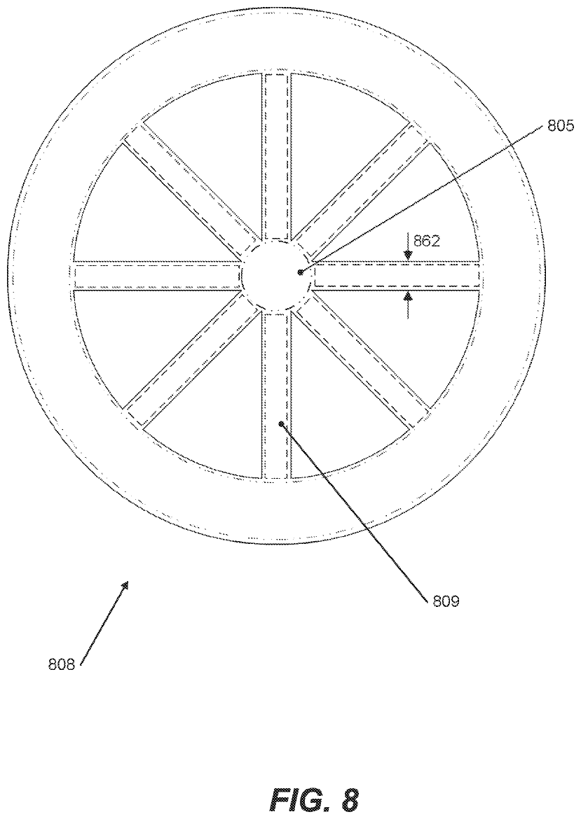

The geometry of the coupling between the annular portion and the spokes may affect non-uniformity of processing operations. Without being bound by theory, the RF density may vary between where the spoke connects to the annular portion and the annular portion that is furthest from any spoke. Rounding the interior corners between the spokes and the annular portion may reduce variability in the RF density along the annular portion, thereby reducing wafer edge non-uniformity. In some embodiments, the interior corners formed where each spoke couples to the annular portion may be rounded or filleted. FIG. 7 presents a view of a single coupling between a spoke 709 and annular portion 722 of a blocking electrode 708 having a rounded corner 748. The dashed line indicates a non-rounded corner. In some embodiments, each corner may have a radius 750. In some embodiments, the radius is at least about 0.08 inches or between about 0.08 inches and about 1 inch.

In some embodiments, the clamping electrodes may be similarly rounded where they are above rounded corners of the blocking electrode, as shown by electrode 706. As discussed herein, the blocking electrode may electromagnetically couple to the chucking electrodes where there is horizontal overlap, diminishing the electromagnetic coupling between the clamping electrodes and the wafer, which is undesirable and potentially wasteful. Thus, in some embodiments the clamping electrodes shape may match the filleted corners between the spokes and annular portion of the blocking, thereby reducing overlap between the clamping electrodes and the blocking electrode.

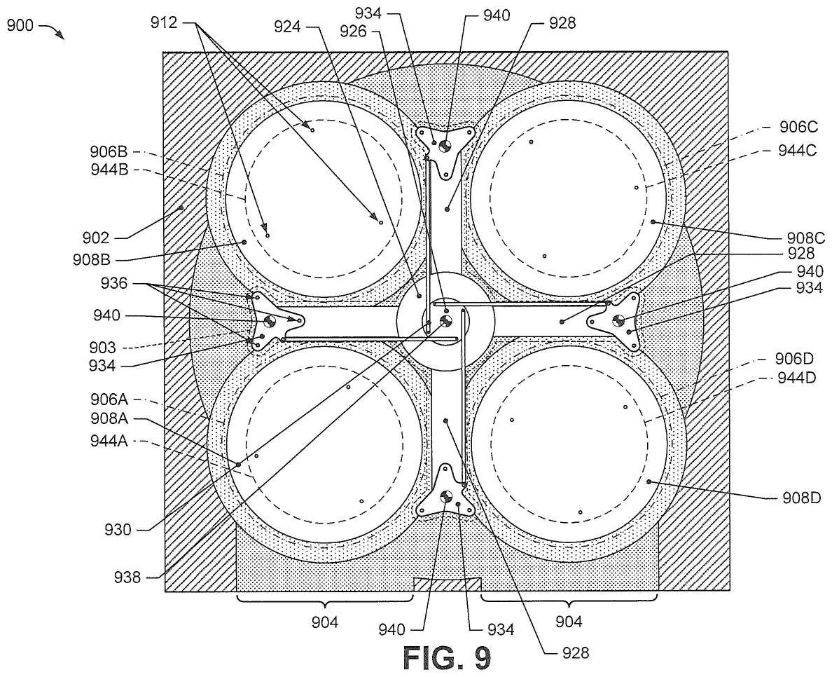

In some embodiments, increasing the thickness of the spokes in directions perpendicular to a radius along with that spoke extends may also reduce RF density variability. FIG. 8 presents a diagram of a blocking electrode 808 having 8 spokes 809 connected to a center region 805. Each spoke width 862 may be added to determine a ratio of total spoke width:circumference, where the circumference is the circumference of a circle that is co-radial with the inner edge of the annular portion. In some embodiments the ratio of total spoke width to circumference is at least about 1:100 or at least about 1:10. For example, if the total inner circumference of the blocking electrode is about 35.5 inches (based on a 11.3 inch inner diameter), the total width of the spokes may be at least about 3.5 inches. In some embodiments, the width of each spoke may be between about 0.1 inch and about 0.5 inches.

As noted above, in some embodiments rotating the wafer relative to the spokes of a blocking electrode (or relative to the spokes of multiple blocking electrodes) between processing operations may reduce non-uniformities. Embodiments herein may reduce such peak non-uniformity without rotation. In some implementations, peak non-uniformity may be reduced further by using embodiments herein as well as rotation between processing operations. In some embodiments, a wafer may be rotated between processing operations. Such rotations may, for example, be performed using an indexer or other wafer handling system that is configured to be able to rotate a wafer relative to a given pedestal and then place the wafer back down onto the given pedestal with a new rotational orientation relative to the pedestal.

FIG. 9 depicts an example of a multi-station chamber with an example rotational indexer system. In FIG. 9, a semiconductor processing tool 900 is shown that includes a chamber 902 that has four wafer processing stations 906 (A-D) within it, each of which has a corresponding pedestal 908 (A-D) which is configured to support a corresponding wafer 944 (A-D). Each pedestal 908 may be an ESC according to various embodiments herein. The chamber 902 may, for example, have one or more wafer transfer ports 904 that may be provided to allow wafers 944 to be placed on, or removed from, some of the pedestals 908 by, for example, a wafer handling robot located outside of the chamber 902.

The semiconductor processing tool 900 may also include a rotational indexer 903, which may have a plurality of indexer arms 928 that have proximal ends that are fixedly connected with a central hub 924 that is configured to rotate about a first axis 938 (the first axis 938 will be understood to be perpendicular to the plane of the page with respect to FIG. 9) and distal ends on which corresponding rotatable wafer supports 934 are provided. Each rotatable wafer supports 934 may, for example, have a plurality of features, such as contact pads 936, that may be designed to stably support one of the wafers 944 from beneath during indexing operations.

The indexer 903 also includes a second hub 926 that is able to be independently driven with respect to the central hub 924. The second hub 926, for example, may be connected with a plurality of tie rods 930 that may each be connected at their opposing ends with a corresponding one of the rotatable wafer supports 934 so that when the central hub 924 and the second hub 926 are rotated relative to each other, the rotatable wafer supports 934 undergo similar relative rotation. Rotating both the central hub 924 and the second hub 926 in the same direction and at the same speed will instead cause the indexer arms 928 to rotate in unison without any rotation of the rotatable wafer supports 934 relative to the indexer arms 928.

The pedestals 908 of the semiconductor processing tool 900 may also include a plurality of lift pins 912 at each wafer processing station 906 that are able to be extended or retracted relative to the corresponding pedestal 908 so as to cause the wafer 944 that may be resting on the corresponding pedestal 908 to be lifted off of, or lowered onto, the underlying pedestal 908.

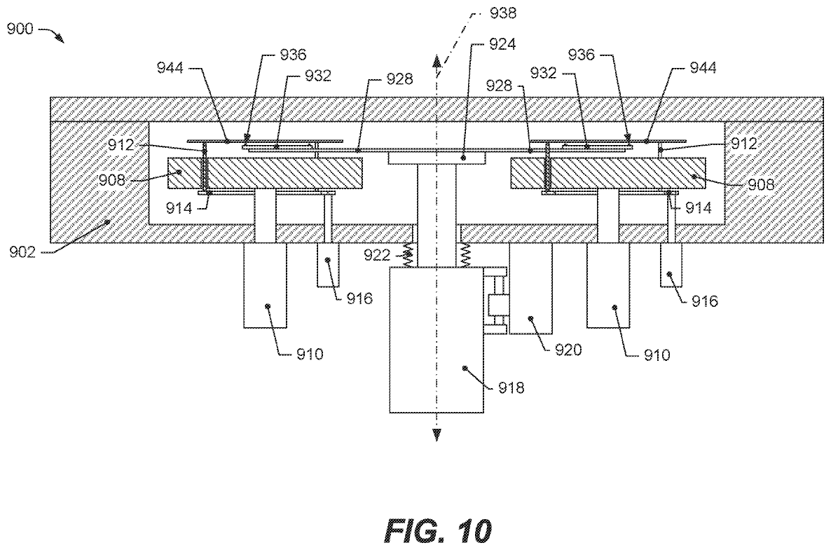

FIG. 10 depicts a diagonal section view of the multi-station chamber of FIG. 9. In FIG. 10 it can be seen that the lift pins 912 may extend through the pedestal, e.g., via through-holes in the pedestal, and may be connected with a lift pin ring 914 that allows the lift pins 912 to be moved up and down relative to the pedestal and in unison responsive to movement of a lift pin actuator 916. The lift pins 912 may generally have uppermost surfaces that are intended to contact the underside of the wafer 944 and support the wafer 944 from below. The lift pins 912 may generally be movable such that those uppermost surfaces can be transitioned between locations that are above and below the uppermost surface of the pedestal 908. Other lift pin mechanisms may be used as well, e.g., independently driven lift pins at each wafer processing station. The lift pins 912 may be actuated so as to lift a wafer 944 that is resting on the top of one of the pedestals 908 clear of that pedestal 908 such that a gap exists between the pedestal 908 and the wafer 944 that is sufficiently large enough that the indexer arms 928 and rotatable wafer supports 934 can pass in between the wafers 944 and the pedestals 908. When the wafers 944 are lowered onto the rotatable wafer supports 934, they may come to rest on contact pads 936, which may provide support to the wafers 944 with a relatively minimal amount of contact between the wafers 944 and the rotatable wafer supports 934.

The rotational indexer 903 may have an indexer drive assembly 918 that may include motors that may be controlled so as to rotate the central hub 924 and the second hub 926 (in unison), and thus the indexer arms 928 and the rotatable wafer supports 934, about a first axis 938, or the rotatable wafer supports 934 relative to the indexer arms 928 about their respective centers of rotation 940 (by rotating the second hub 926 relative to the central hub 924). In some implementations, the indexer drive assembly 918 may also be mounted to a lift actuator 920, in which case a bellows seal 922 may be provided to seal the opening in the chamber 902 through which the central shaft of the rotational indexer 903 may pass. This may allow the indexer arms 928 to be moved up and down as a unit.

During use, the wafers 944 may be raised into elevated positions by the lift pins 912 while the rotational indexer 903 is positioned such that the indexer arms 928 are each interposed between different sets of adjacent pedestals 908. Once the wafers 944 are in the elevated positions, the rotational indexer 903 may be actuated so as to cause the rotatable wafer supports 934 to swing into position beneath each wafer 944. When the rotatable wafer supports 934 are all positioned underneath a corresponding wafer 944, the lift pins 912 may be retracted and the wafers 944 lowered until they come to rest on the rotatable wafer supports 934 positioned beneath the wafers 944. The lift pins 912 may continue to be retracted until they no longer extend into the rotational path of the indexer, thereby allowing the rotational indexer 903 to be rotated about the first axis 938 and the wafers 944 to be transported along arcuate paths from one wafer processing station 906 to another. After the rotational indexer 903 has been actuated so as to cause the wafers 944 to be moved between different wafer processing stations 906, the lift pins 912 may be extended again, lifting the wafers 944 off of the rotatable wafer supports 934. Once the wafers 944 are no longer supported by the rotatable wafer supports 934, the rotational indexer 903 may be actuated again to rotate the indexer arms 928 so that the rotatable wafer supports 934 are no longer beneath the wafers 944. Once the rotatable wafer supports 934 are no longer beneath the wafers 944, the lift pins 912 may again be actuated so as to retract them into the pedestals 908, thereby lowering the wafers 944 onto the pedestals 908.

Alternatively, the indexer arms 928 may be kept stationary and the second hub 926 rotated relative to the central hub 924 so as to cause the rotatable wafer supports 934 (with wafers supported thereby) to rotate relative to the indexer arms 928 and thus the pedestals 908. The rotated wafers may then be re-placed on the same pedestals from which they were picked, but with a different rotational orientation relative to those pedestals. In some instances, wafers may be both moved between stations and rotated so as to have different relative rotational orientations relative to similar features (e.g., electrodes) in each pedestal that each wafer is placed on.

Further discussion of rotational indexers with the ability to rotate wafers in-place may be found in U.S. patent application Ser. No. 15/867,599, titled “ROTATIONAL INDEXERS WITH ADDITIONAL ROTATIONAL AXES,” which is hereby incorporated herein for all purposes.

In some embodiments, the indexer of FIG. 9 may be configured to rotate the rotatable wafer supports 934 based on the configuration of the spokes in a blocking electrode of an ESC that is part of a wafer processing station. For example, wafers may be picked up off a pedestal by lift pins and then placed onto a rotational indexer such as that described above. The wafers may then be rotated in-place by some amount using the indexer prior to being lifted back off the indexer by the lift pins and then placed back onto the pedestals from which they were obtained. In some embodiments, the amount of rotation provided during each such rotational movement may be based on an angle between spokes of the blocking electrode. Thus, any peaks of non-uniformity in processing operations that correspond to a spoke may be reduced by changing the position of the spokes relative to a wafer being processed, and thus the location of non-uniformities on that wafer. In some embodiments, a processor may cause the rotatable wafer supports 934 to rotate by an amount that results in location on wafer that was centered on a radial centerline of a spoke pre-rotation to be rotationally offset, with respect to the blocking electrode center, from that radial centerline post-rotation. In some embodiments, the rotational offset for each rotation may be 360°/N/(x+1), where N=number of spokes and x=number of rotations that a wafer will be subjected to. Thus if the blocking electrode has four spokes and a wafer will be rotated twice (thus being in a first rotational position, second rotational position, and then a third rotational position), the wafer would be rotated by 30° each time it is rotated. The wafer would thus be processed three times, with the spokes at 0/90/180/270, 30/120/210/300, and 60/150/240/330 relative to the pedestal during each processing operation. In some embodiments wafer rotation may occur during transfer between stations (i.e., the wafer may be rotated relative to different electrodes in different pedestals by different amounts, e.g., similar to what may occur when the wafer remains on the same pedestal. In other embodiments, as discussed above, wafers may be rotated without transferring stations, staying at a single station but being rotated relative to the station for successive processing operations.

As noted above, in some implementations a controller 311 is part of a system, which may be part of the above-described examples, including the rotational indexer shown in FIGS. 9 and 10. Such systems can include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller 311, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings in some systems, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the processing of one or more layers, materials, metals, oxides, silicon, silicon dioxide, surfaces, circuits, and/or dies of a wafer.

The controller, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of processing operations, examine a history of past processing operations, examine trends or performance metrics from a plurality of processing operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the processing and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

### CONCLUSION

System and methods have now been provided that provide improved plasma generation capabilities over conventional systems. The above-described plasma generator systems experience a reduced downtime between plasma generation processes as compared to conventional systems, and they do so while reducing exposure of surrounding system components to high amounts of power. As a result, the improved plasma generator systems now include components, such as RF components, gas flow distributors and tubes, having improved useful lives compared to components of conventional plasma generator systems. Additionally, maintenance costs of the systems are reduced as well.

It is to be understood that the phrases “for each <item> of the one or more <items>,” “each <item> of the one or more <items>,” or the like, if used herein, are inclusive of both a single-item group and multiple-item groups, i.e., the phrase “for . . . each” is used in the sense that it is used in programming languages to refer to each item of whatever population of items is referenced. For example, if the population of items referenced is a single item, then “each” would refer to only that single item (despite the fact that dictionary definitions of “each” frequently define the term to refer to “every one of two or more things”) and would not imply that there must be at least two of those items. Similarly, the term “set” or “subset” should not be viewed, in itself, as necessarily encompassing a plurality of items—it will be understood that a set or a subset can encompass only one member or multiple members (unless the context indicates otherwise).

The use, if any, of ordinal indicators, e.g., (a), (b), (c) . . . or the like, in this disclosure and claims is to be understood as not conveying any particular order or sequence, except to the extent that such an order or sequence is explicitly indicated. For example, if there are three steps labeled (i), (ii), and (iii), it is to be understood that these steps may be performed in any order (or even concurrently, if not otherwise contraindicated) unless indicated otherwise. For example, if step (ii) involves the handling of an element that is created in step (i), then step (ii) may be viewed as happening at some point after step (i). Similarly, if step (i) involves the handling of an element that is created in step (ii), the reverse is to be understood. It is also to be understood that use of the ordinal indicator “first” herein, e.g., “a first item,” should not be read as suggesting, implicitly or inherently, that there is necessarily a “second” instance, e.g., “a second item.”

The term “between,” as used herein and when used with a range of values, is to be understood, unless otherwise indicated, as being inclusive of the start and end values of that range. For example, between 1 and 5 is to be understood to be inclusive of the numbers 1, 2, 3, 4, and 5, not just the numbers 2, 3, and 4.

Various modifications to the implementations described in this disclosure may be readily apparent to those skilled in the art, and the generic principles defined herein may be applied to other implementations without departing from the spirit or scope of this disclosure. Thus, the claims are not intended to be limited to the implementations shown herein, but are to be accorded the widest scope consistent with this disclosure, the principles and the novel features disclosed herein.

Certain features that are described in this specification in the context of separate implementations also can be implemented in combination in a single implementation. Conversely, various features that are described in the context of a single implementation also can be implemented in multiple implementations separately or in any suitable sub-combination. Moreover, although features may be described above as acting in certain combinations and even initially claimed as such, one or more features from a claimed combination can in some cases be excised from the combination, and the claimed combination may be directed to a sub-combination or variation of a sub-combination.

Similarly, while operations are depicted in the drawings in a particular order, this should not be understood as requiring that such operations be performed in the particular order shown or in sequential order, or that all illustrated operations be performed, to achieve desirable results. Further, the drawings may schematically depict one more example processes in the form of a flow diagram. However, other operations that are not depicted can be incorporated in the example processes that are schematically illustrated. For example, one or more additional operations can be performed before, after, simultaneously, or between any of the illustrated operations. In certain circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products. Additionally, other implementations are within the scope of the following claims. In some cases, the actions recited in the claims can be performed in a different order and still achieve desirable results

1. An apparatus comprising an electrostatic chuck (ESC) for supporting a semiconductor substrate, the ESC comprising:
an upper surface for supporting a wafer;
one or more clamping electrodes beneath the upper surface, wherein the one or more clamping electrodes are configured to, when powered, electrostatically clamp the wafer to the upper surface;
a blocking electrode, wherein the blocking electrode comprises:
an annular portion,
a center portion, and
three or more spokes, wherein each spoke has a distal end coupled to the annular section and a proximal end coupled to center portion,
wherein the annular section surrounds the one or more clamping electrodes when viewed along an axis perpendicular to the upper surface.

2. The apparatus of claim 1, wherein the one or more clamping electrodes are configured to be powered by an RF source.

3. The apparatus of claim 1, wherein a distance between a top surface of the blocking electrode and a bottom surface of the one or more clamping electrodes is between about 0.05 and about 0.2 inches.

4. The apparatus of claim 1, wherein interior corners formed where each of the three or more spokes is coupled to the annular portion are rounded.

5. The apparatus of claim 1, wherein the three or more spokes are arranged in a radially symmetric pattern.

6. The apparatus of claim 1, wherein there are 2·n spokes, where n is an integer greater than one.

7. The apparatus of claim 1, wherein the three or more spokes are 10 spokes.

8. The apparatus of claim 1, wherein the one or more clamping electrodes are two clamping electrodes.

9. The apparatus of claim 8, wherein the two clamping electrodes are configured to, when powered by an radio frequency (RF) source, operate at a positive and negative polarity, respectively.

10. The apparatus of claim 8, wherein the two clamping electrodes are nominally semicircular electrodes.

11. The apparatus of claim 1, wherein the one or more clamping electrodes are planar.

12. The apparatus of claim 1, wherein the blocking electrode is planar.

13. The apparatus of claim 1, wherein the blocking electrode comprises a metal mesh.

14. The apparatus of claim 1, wherein the blocking electrode comprises a single piece of metal.

15. The apparatus of claim 1, wherein the apparatus further comprises an RF power source, and wherein the number of spokes of the blocking electrode is based on a frequency of the RF power source.

16. The apparatus of claim 1, wherein the one or more clamping electrodes are parallel to the blocking electrode and between the blocking electrode and the upper surface.

17. The apparatus of claim 1, wherein one or more clamping electrodes are at least two clamping electrodes, and wherein at least one spoke of the three or more spokes are aligned with a gap between the one or more clamping electrodes when viewed along the first axis.

18. The apparatus of claim 1, wherein each spoke has a width measured in a direction perpendicular to the first axis perpendicular to the upper surface and the proximal and distal ends of each spoke, and wherein a ratio between the total width of all spokes and the inner circumference of the annular section portion is greater than about 1:10.

19. The apparatus of claim 1, wherein the apparatus further comprises lift pins that do not intersect the three or more spokes.

20. The apparatus of claim 1, wherein the apparatus further comprises a process chamber that contains the ESC.

21. The apparatus of claim 1, wherein the apparatus further comprises a rotational indexer.

22. The apparatus of claim 21, wherein the rotational indexer comprises a central hub and an indexer arm, the central hub rotatable relative to the chamber about a first axis nominally located at the center of the circular pattern, each indexer arm having a proximal end fixedly mounted to the central hub and a distal end that supports a rotatable wafer support that is configured to rotate about a corresponding second axis relative to the indexer arms, and wherein the apparatus further comprises a controller that includes one or more processors and one or more memories, wherein:
the one or more processors, the one or more memories, the ESC, the indexer, and the process chamber are operably connected with each other, and
the one or more memories store computer-executable instructions for controlling the one or more processors to:
cause a wafer located on the ESC to be placed on the rotatable wafer support;
cause the rotatable wafer support and the wafer supported thereby to rotate about the corresponding second axis by an amount based at least in part on an angle between two adjacent spokes of the three or more spokes of the blocking electrode; and
cause the wafer to be placed back onto the ESC.
